(19) United States
(12) Patent Application Publication
(10) Pub. No.: US 2008/0145769 A1
(43) Pub. Date: Jun. 19, 2008

(54) SIMULATION METHOD, SIMULATION SYSTEM, AND METHOD OF CORRECTING MASK PATTERN

(75) Inventor: Yukiya Kawakami, Kanagawa (JP)

Correspondence Address: YOUNG & THOMPSON, 209 Madison Street, Suite 500, ALEXANDRIA, VA, 22314, US

(73) Assignee: NEC ELECTRONICS CORPORATION, KANAGAWA (JP)

(21) Appl. No.: 11/956,439

(22) Filed: Dec. 14, 2007

(30) Foreign Application Priority Data
Dec. 18, 2006 (JP) 2006-340161

(51) Int. Cl. G03F 1/00; G06F 17/50; G03C 5/00

(52) U.S. Cl. 430/5; 716/21; 430/311

(57) ABSTRACT

A simulation system has an entry acceptance unit, a calculation unit, and a decision unit. The entry acceptance unit accepts an entry of measured dimension of the transfer pattern, the calculation unit includes an electric field vector calculation unit, a flare electric field vector calculation unit and a light intensity calculation unit. The electric field vector calculation unit calculates triaxial vector components of electric field at every position, the flare electric field vector calculation unit calculates a flare electric field vector based on polarization ratio of an exposure tool, and based on tentative horizontal ratio and tentative vertical ratio on the wafer surface for every position, the light intensity calculation unit calculates light intensity by adding the electric field vector and the flare electric field vector so as to calculate sum of squares of the triaxial components.

This application is based on Japanese patent application No. 2006-340161 the content of which is incorporated hereinto by reference.

### BACKGROUND

1. Technical Field

The present invention relates to a simulation method and a simulation system used in photolithography through a mask in the process of manufacturing semiconductor devices or liquid crystal display devices, aimed at obtaining a desired photoresist pattern well conforming to a designed pattern, and a method of correcting a mask pattern.

2. Related Art

Recent progress in semiconductor manufacturing technologies has realized manufacturing of semiconductor integrated circuit having a minimum process dimension of 90 nm or smaller. This level of dimensional shrinkage has been enabled by advancement in micro-patterning technologies such as mask processing technology, photolithographic technology and etching technology. In the age where steppers used i-line or g-line, and the pattern size was sufficiently larger than the wavelength of light, an LSI pattern satisfying the design rules required for the individual portions could successfully be formed by directly transferring a planar geometry of the LSI pattern, which is desired to be formed on a wafer, to a mask, further transferring the obtained mask pattern through an optical projection system onto a wafer, and etching a layer desired to be patterned (for example, semiconductor substrate, semiconductor film, insulator film, conductor film) lying under the mask pattern. However, advancement in shrinkage of the pattern has been making it more difficult to exactly transfer and form the pattern in the individual processes, and consequently making it impossible for the finally-attainable critical dimension (CD) to reproduce the critical dimension (CD) of the original LSI pattern.

In particular for the lithography and etching process, which are most important for attaining micro-processing, a problem has been arisen in that a targeted dimensional accuracy (CD accuracy) has been becoming more largely affected by any pattern layout disposed in the periphery of the target pattern. A technique having been adopted for suppressing such variation is optical proximity correction (OPC), by which edge and/or corner portions in the mask pattern, causative of large variations, are preliminarily deformed so as to adjust the finally-attainable dimensions to the desired values.

With recent increased complication in the OPC technique, it has been becoming more difficult for a designer to predict the dimension finally-attainable on the wafer, because of large difference between an LSI pattern prepared by the designer and the mask pattern practically used in the light exposure. The OPC is, therefore, adopted to the mask pattern according to the procedures below.

First, a lithographic model is prepared by an empirical lithographic simulation, having the measured values (measured CD) obtained from a sample mask pattern and the calculated values (calculated CD) matched therein.

Because the lithographic model can predict, in principle, a pattern geometry of an arbitrary LSI pattern finally attainable on a wafer, so far as conditions for light exposure are kept unchanged from those adopted to the sample mask pattern, the model can provide a guideline on how to adopt the OPC, and whether the adopted OPC is appropriate or not can be confirmed by calculating a pattern geometry attainable on the wafer after the selected OPC technique was adopted.

A prior art document may be exemplified by James Word, et al., “Full Chip Model Based Correction of Flare-Induced Linewidth Variation”, Optical Micrography XVIII, Proceedings of SPIE Vol. 5754 (2005) 1209-1219.

For appropriate OPC, excellence in accuracy both in the measured CD to be entered to an empirical lithographic simulation and accuracy of the empirical simulation per se is essential. Principle and problems in the simulation will be explained below.

FIG. 8 shows, from the top to the bottom, a top view of a mask pattern, a depth-wise distribution of light intensity attainable in a section of a photoresist in the lithographic simulation, and a bottom view of a resolved pattern of the photoresist after the light exposure. Although the mask pattern is generally projected onto the wafer as being shrunk by a factor of ¼ to ⅕, the illustration herein is expressed at an equal magnification for simplicity of understanding. Also shrinkage by projection may be understood as being absolutely identical to the case of equal magnification, if the designed values (mask CD) are considered as the values after being shrunk.

Referring now to FIG. 8, light coming through an opening of the mask produces an intensity distribution depending on positions. In a region where a photochemical reaction proceeds in proportion to the light intensity, and the number of reacted molecules exceeds a certain ratio with respect to the original number of molecules, a positive photoresist shown in FIG. 8 will dissolve into a developing solution (on the contrary, the negative resist will remain after the development). As a consequence, a threshold value of the amount of reacted molecules which determines the resolution power may correspond to a certain value of light intensity. In other words, it is assumed that the border of resolution is determined by a threshold value of a certain light intensity.

FIG. 8 shows an exemplary case of perfect lateral symmetry. The design values (mask CD) and the measured values (measured CD) generally differ from each other. The center portion will be detailed referring to FIG. 9 in the next.

Referring now to FIG. 9, light coming through an opening of the mask produces intensity distribution depending on positions. A coordinate system along which CD increases from the origin placed on the left edge of the mask is assumed as x1 coordinate system, and a coordinate system along which CD increases from the origin placed on the right edge is assumed as x2 coordinate system. A coordinate of the mask can directly be read off from the design data given in a form of electronic data. FIG. 9 is given as being laterally symmetrical. Because two photoresist edges eventually stands on the points shifted by an error value=(measured value−design value)/2, which is a minus value, respectively in the x1 coordinate system and the x2 coordinate system, the coordinate values of both edges will be apparent. By assuming light intensity at both edges (I1(x1),I2(x2)) as a threshold value Th, and by specifying the edges with this threshold value Th under given two-dimensional distribution of light intensity in the lithographic simulation, a resolved pattern of the photoresist can be obtained for any arbitrary mask pattern.

Based on this principle, a most simple empirical lithographic simulation gives light intensity as being adapted to every optical system, and finds optical parameters and average threshold value by regressive calculation or statistical processing, so that the CD, same as the measured CD, may be calculated at a large number of points of measurement. The technique is referred to as lithographic model generation. Once the light intensity and the threshold value (that is, lithographic model) are determined, CD in the resolved pattern of the photoresist is predictable for any arbitrary mask.

At present, reproduction of flare is the most challenging problem in the lithographic simulation. The problem will be explained below.

Flare (or stray light) is a phenomenon inevitably occurs in optical instrument having lenses such as exposure tool, camera, and so forth. The lenses refract the incident light and modify its direction, but reflect an extremely small portion of the incident light to produce reflected light, despite an effort of providing anti-reflective film on the surface thereof. Although all components of the optical system, other than the lenses and mirrors, are generally painted in black so as to absorb the light, the reflected light still may reach the photoresist through the exposure tool, and may reach a film through a camera, after repeating multiple reflection within the lens system, and may produce noise.

The noise is called flare, by association of fluttering flare under irradiation with a strong light source, and also called stray light in connection to its causes. As a result of the countermeasure, the flare in the exposure tool tends to exert a pattern density-dependent effect (loading effect) as the background light, rather than producing error patterns. For a mask pattern having a wide opening, this effect is expressed as elevating the light intensity level at the dark portion due to increase in the stray light.

The flare, which cannot completely be eliminated, should be incorporated into the lithographic simulation, aimed at reproducing an actual resolved pattern using the exposure tool. It is, however, not easy to exactly reproduce the flare, because it is caused by multiple reflection of light inside the optical system. At present, a technique of providing the loading effect to a binary mask having values of 0 and 1 only has been disclosed by James Word, et al. According to this technique, light intensity is first calculated by a general optical calculation, next a convolution integral of a mask function expressing an opening pattern of the mask and Gaussian function of diffusion length DL is calculated, the result is multiplied by a constant so as to convert the unit into that of light intensity, and the results are added to the light intensity determined by the above-described optical calculation. However, in the technique disclosed by James Word, et al., even the binary mask has a still large NA enough to allow strong polarization of light from the light source, so that it is insufficient to consider the flare only in terms of light intensity, raising a further need of improving accuracy of the lithographic simulation.

On the other hand, when considering an actual phase shift mask, the flare appears as being corresponded both to the 0-phase and the π-phase. The flare in the 0-phase exerts an addition effect of light intensity to the normal light in the 0-phase, but a subtraction effect of light intensity to the normal light in the π-phase. On the contrary, the flare in the π-phase exerts a subtraction effect of light intensity to the normal light in the 0-phase, but an addition effect of light intensity to the normal light in the π-phase.

Therefore, in an effort of reproducing the actual flare, a merely simple assumption that the flare in the 0-phase is given with a positive value and the flare in the π-phase is given with a negative value results in that the flare in the 0-phase exerts an addition effect of light intensity to the normal light in the 0-phase, and exerts an addition effect of light intensity also to the normal light in the π-phase. On the other hand, the flare in the π-phase exerts a subtraction effect of light intensity to the normal light in the 0-phase, and exerts a subtraction effect of light intensity also to the normal light in the π-phase. These results are different from the predicted effects, suggesting that the assumption is not correct, and that the problem is not so simple. It is therefore understood that the phase shift mask needs addition of another loading effect different from that added to the binary mask.

However in the method of James Word, et al., a convolution integral of the opening of the mask pattern and Gaussian function of sigma (diffusion length, expressed as DL in this embodiment) is calculated, and the result is added as the loading effect to the above-described light intensity distribution. Therefore, the phase shift mask, represented by Levenson mask, has failed in incorporating the loading effect, and has consequently failed in improving accuracy of the lithographic simulation.

As has been described in the above, the method described by James Word, et al. has been suffered from a problem to be solved, in the effort of improving accuracy of the lithographic simulation.

### SUMMARY

According to the present invention, there is provided a simulation method acquiring, by simulation, information on a transfer pattern realizable on a wafer as a result of photolithographic transfer of a mask pattern of a predetermined mask, which includes accepting an entry of measured dimension of the transfer pattern; calculating an electric field vector for every predetermined position in a plane coordinate defined on the surface of the wafer; calculating a flare electric field vector ascribable to the mask pattern for every predetermined position; adding the flare electric field vector to the electric field vector, and obtaining sum of squares of their triaxial vector components, to thereby calculate a light intensity distribution; and assuming a threshold value of light intensity observed for the edges at paired two points specifying calculated dimension of the transfer pattern in the simulation as an unknown constant, and determining, by regressive calculation, the threshold value so as to minimize difference between the calculated dimension and the measured dimension under the given light intensity.

According to the present invention, there is provided also a simulation system acquiring, by simulation, information on a transfer pattern realizable on a wafer as a result of photolithographic transfer of a mask pattern of a predetermined mask, which includes a unit of accepting an entry of measured dimension of the transfer pattern; a unit of calculating an electric field vector for every predetermined position in a plane coordinate defined on the surface of the wafer; a unit of calculating a flare electric field vector ascribable to the mask pattern for the every predetermined position; a unit of adding the flare electric field vector to the electric field vector, and obtaining sum of squares of their triaxial vector components, to thereby calculate a light intensity distribution;

and a unit of assuming a threshold value of light intensity observed for the edges at paired two points specifying calculated dimension of the transfer pattern in the simulation as an unknown constant, and determining, by regressive calculation, the threshold value so as to minimize difference between the calculated dimension and the measured dimension under the given light intensity.

In the simulation method and the simulation system configured as described in the above, the loading effect is incorporated by adding a flare electric field vector to an electric field vector. By virtue of this configuration, a highly accurate lithographic model for OPC can be obtained, and a desired transfer pattern can consequently be obtained under high accuracy.

According to the present invention, there is provided also a method of correcting a mask pattern using a lithographic model obtainable by the simulation method of the present invention.

Because the correction method uses a lithographic model obtainable by the simulation method described in the above, a mask pattern capable of producing a desired transfer pattern may be obtained under high accuracy. Yield of the photomask may therefore be improved.

According to the present invention, there is provided still also a photomask having a corrected mask pattern obtainable by the method of correcting a mask pattern described in the above.

According to the present invention, there is provided still also a method of manufacturing a semiconductor device which includes forming a resist film on a substrate; forming a pattern in the resist film by light exposure through the photomask described in the above, and development; and processing the substrate using the resist film having the pattern transferred thereto.

With this photomask, a desired transfer pattern may be obtained under high accuracy. As a consequence, a desired transfer pattern may be formed in the resist film in the method of manufacturing a semiconductor device, and yield of the product may be improved.

The threshold value of light intensity in the present invention means a value of light intensity attainable at a position in the photoresist after light exposure, where a border between resolution and non-resolution with the aid of developing solution is determined.

According to the present invention, a highly accurate method of lithographic simulation may be provided, and a desired transfer pattern may be obtained under high accuracy.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is block diagram showing a first embodiment of a simulation system according to the present invention;

FIG. 2 is a flow chart of calculation procedures according to the first embodiment;

FIG. 3 is a drawing showing a first aspect of essential calculation processes of the first embodiment;

FIG. 4 is a drawing showing a second aspect of essential calculation processes of the first embodiment;

FIG. 5 is a flow chart of calculation procedures according to the second embodiment;

FIG. 6 is a drawing showing a first aspect of essential calculation processes of the second embodiment;

FIG. 7 is a drawing showing a second aspect of essential calculation processes of the second embodiment;

FIG. 8 is a drawing showing, from the top to the bottom, a top view of a laterally-symmetrical mask pattern, a depth-wise distribution of light intensity attainable in a section of photoresist in the lithographic simulation, and a bottom view of a resolved pattern of the photoresist after the light exposure;

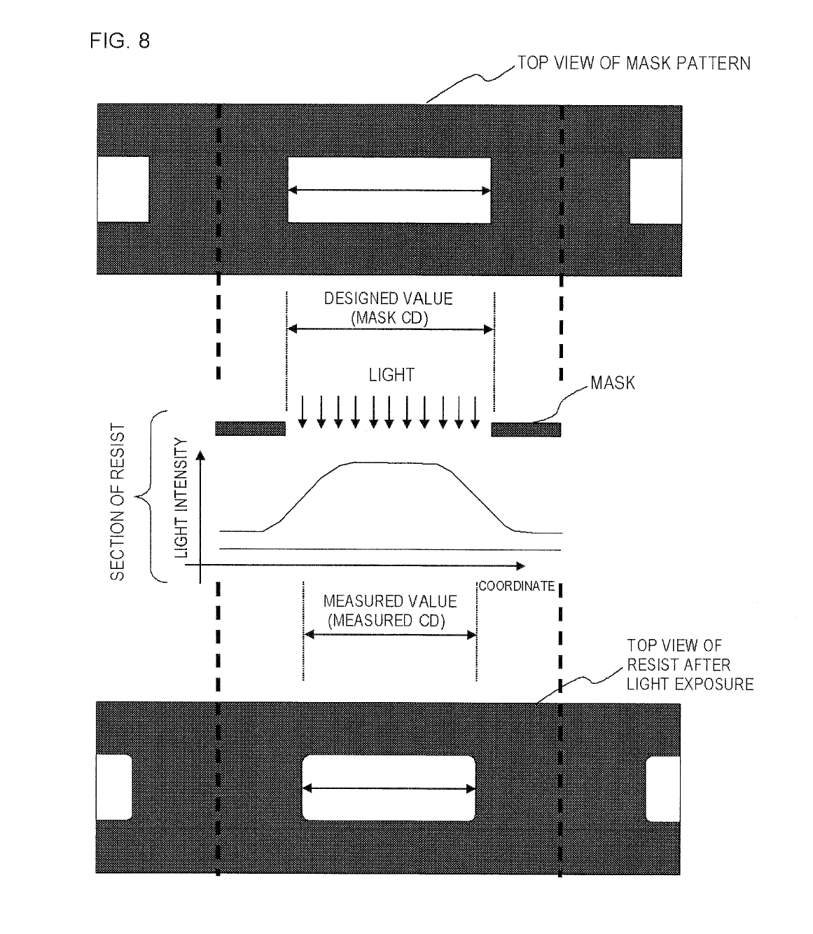

FIG. 9 is a drawing showing interrelation among a depth-wise intensity distribution in the photoresist, design value (mask CD), measured value (measured CD) and error value in the lithographic simulation of a laterally-symmetrical pattern;

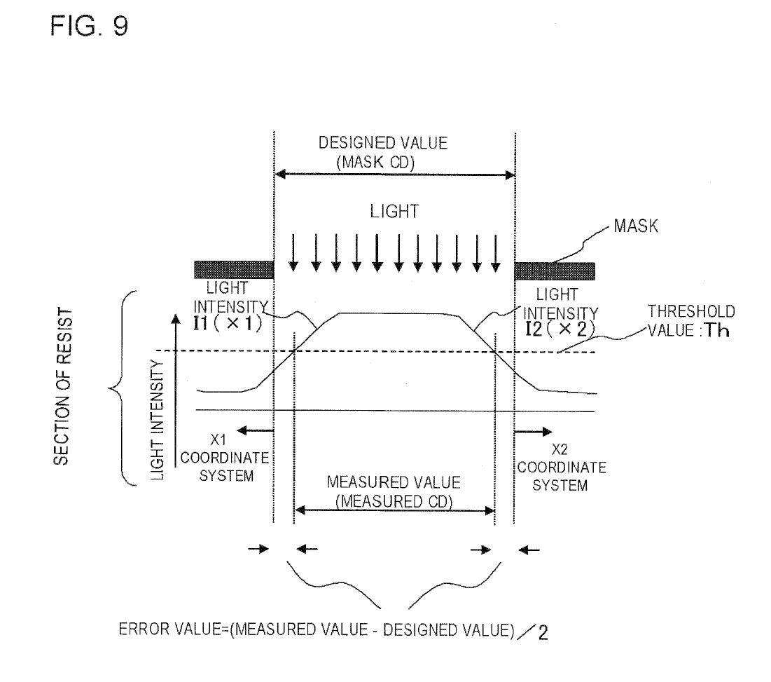

FIG. 10 is a flow chart of calculation procedures of a conventional example;

FIG. 11 is a drawing showing a first aspect of essential calculation processes of a comparative conventional example;

FIG. 12 is a drawing showing a second aspect of essential calculation processes of a comparative conventional example; and

FIG. 13 is a drawing showing a third aspect of essential calculation processes of a comparative conventional example.

### DETAILED DESCRIPTION

The invention will now be described herein with reference to an illustrative embodiments. Those skilled in the art will recognize that many alternative embodiments can be accomplished using the teachings of the present invention and that the invention is not limited to the embodiment illustrated for explanatory purposes.

Paragraphs below will explain the embodiments of the present invention referring to the attached drawings. In all drawings, any similar constituents will be given with similar reference numerals, and explanation therefor will not be repeated.

Embodiments of the present invention will be explained below, referring to the attached drawings.

### FIRST EMBODIMENT

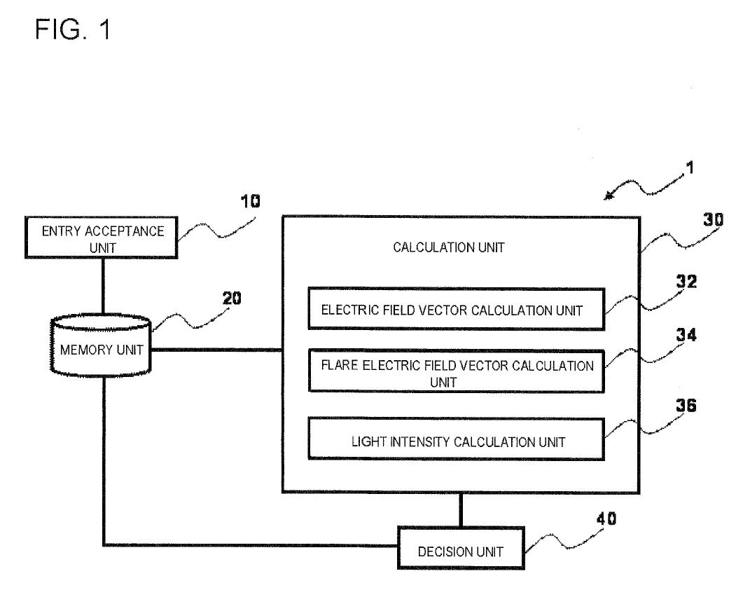

FIG. 1 is a block diagram showing a first embodiment of a simulation system according to the present invention. A simulation system 1 is a simulation system acquiring, by simulation, information on a transfer pattern realizable on a wafer as a result of photolithographic transfer of a mask pattern of a predetermined mask, and has an entry acceptance unit 10, a memory unit 20, a calculation unit 30, and a decision unit 40.

The entry acceptance unit 10 is a means for accepting an entry of measured dimension of the transfer pattern. The entry acceptance unit 10 may be exemplified by keyboard and mouse.

The memory unit 20 is a means for storing simulation parameters such as measured dimension entered through the entry acceptance unit 10. The memory unit 20 may be exemplified by memories such as RAM and ROM. The memory unit 20 may have, stored therein, values of electric field vector, light intensity and so forth, calculated by the calculation unit 30 described later.

The calculation unit 30 includes an electric field vector calculation unit 32, a flare electric field vector calculation unit 34, and a light intensity calculation unit 36. The calculation unit 30 may be exemplified by CPU.

The electric field vector calculation unit 32 is a means for calculating triaxial component of electric field at every position. The flare electric field vector calculation unit 34 is a means for calculating triaxial components of flare electric field at every position, based on a mask pattern, diffusion length, ratio of polarization and ratio of horizontal/vertical direction of a light source. The light intensity calculation unit 36 is a means for calculating light intensity, by adding the electric field vector and the flare electric field vector, and obtaining sum of squares of the triaxial vector components after the addition, to thereby calculate a light intensity distribution.

The decision unit 40 is a means for assuming a threshold value of light intensity observed for the edges at paired two points specifying calculated dimension of the transfer pattern in the simulation as an unknown constant, and determining, by regressive calculation, the threshold value so as to minimize difference between the calculated dimension and the measured dimension under the given light intensity. The decision unit 40 may be exemplified by CPU.

Next, the first embodiment of the simulation method of the present invention will be explained.

First, a method of calculating light intensity for the case adopting a phase shift mask will be explained.

A principle of cancellation of beams of light having phases shifted by π from each other in a phase shift mask will be explained. Light is a transverse wave causing electric field and magnetic field oscillating in the direction normal to the direction of propagation. Direction of oscillation of the magnetic field is normal to the direction of oscillation of the electric field. Amplitude of the magnetic field is determined corresponding to amplitude of the electric field, wherein sum of squares of the electric field and the magnetic field corresponds to the light intensity. Square of the electric field herein means a sum of squares of the individual components projected in three directions, because the electric field is expressed by a three-dimensional vector.

Based on an energy characteristic that square of the electric field becomes equal to square of the magnetic field, assumption is now made such that square of the electric field is proportional to the light intensity. Considering now a point of intersection of two beams of light, three components of electric field vector at that point are given by the sum of three components, and three components of electric field vector of the other beam of light, added by every component, and light intensity is given by the sum of squares of the individuals.

It is assuming now that two beams of light have the same wavelength, same intensity, same direction of propagation, and same direction of oscillation of electric field (the same direction of polarization). If the periodicities of oscillation of the beams shift by half-wavelength or half-period from each other, direction of the electric field of one beam will be opposite to direction of the electric field of the other beam, giving a synthetic electric field of 0. Also the magnetic field will be 0 by the same reason.

This may be expressed by equations of vectors as described in the next. Only the electric field will now be taken into consideration for simplicity. At a position to be concerned, electric field components of one beam of light is given as (Ex1,Ey1,Ez1), light intensity of one beam alone is given as I1=(Ex1)²+(Ey1)²+(Ez1)², electric field components of the other beam of light is given as (Ex2,Ey2,Ez2), and light intensity of the other beam alone is given as I2=(Ex2)²+(Ey2)²+(Ez2)². If both beams of light overlap, the electric field components are given as (Ex1+Ex2, Ey1+Ey2, Ez1+Ez2), and light intensity is given as I=(Ex1+Ex2)²+(Ey1+Ey2)²+(Ez1+Ez2)².

If two beams of light have the same wavelength, same intensity, same direction of propagation, same polarization, but different phases shifted by π (or 180°) from each other, the relations Ex1=−Ex2, Ey1=−Ey2 and Ez1=−Ez2 hold, making the electric field components have a value of 0, making also the magnetic field have a value of 0, and thereby making the light intensity have a value of 0. Even when the beams have directions of propagation only slightly different from each other, they may be canceled if they have phases shifted by π, and thereby the light intensity is lowered although not being zeroed. For an exemplary case of exposing a positive-type photoresist, the adjacent beams having the same phase increases the light intensity so as to widen the region to be developed, whereas the adjacent beams having the phases inverted from each other overlap to reduce the light intensity, so as to narrow the region to be developed, contributing to finer patterning. This is a principle of the phase shift mask.

In other words, the principle of cancellation of the beams having phases shifted by π from each other is not based on simple summation of their light intensity values, but based on the technique of first respectively adding the individual components of the electric field vector of the beams so as to convert them into the light intensity. Therefore, in consideration of the loading effect of the phase shift mask, rather than adding the light-intensity-based loading effect to the light intensity obtained by general optical calculation described by James Word, et al., the present invention saves data of the electric field vector before being converted into light intensity, in the process of calculating the light intensity by the general optical calculation, then calculates a convolution integral of a mask function and Gaussian function, multiplies the result by a constant so as to convert the unit into that of light intensity, wherein the result being called as flare electric field vector, then adds the result to the electric field vector determined by the above-described optical calculation, and converts thus-synthesized electric field vector into light intensity.

In this case, the constant of the loading effect is expressed by triaxial components because the electric field has a vector feature, and the diffusion length DL is given as an unknown constant. These are handled as constants for adjustment similar to the optical parameters, and the threshold value is determined as being optimized by regressive calculation or statistical processing.

Next, as the simulation method of the first embodiment of the present invention carried out according to the above-described method of calculating light intensity, an exemplary operation of the simulation system 1 will be explained. First, the outline will be given.

First, in the lithographic simulation, a triaxial electric field vector (Ex(x,y),Ey(x,y),Ez(x,y)) at position (x,y) is calculated based on the optical parameters.

The mask function Mask(x,y) of the phase shift mask has three values of (+1,0,−1) depending on position (x,y). Value 0 corresponds to the shadowing region, value +1 to the 0-phase opening region, and value −1 to the π-phase opening region. Now, Gaussian function of diffusion length, showing a peak at the origin is given as Gauss (x,y,DL)=(½πDL²)*exp(−(x²+y²)/2πDL²). A first primitive flare Flare1(x,y) is determined as follows:

Flare1(x,y)=Mask(x,y)×Gauss(x,y,DL) (1)

where “×” means an operation of convolution integral.

Surface polarization of the exposure tool is now assumed as (σx,σy,0) (the z-direction is normal to a wafer. Z component of the polarization vector of a light source is 0, because the light propagates in the z-direction).

A first primitive flare vector defined only in a plane is given as (σx*Flare1(x,y), σy*Flare1(x,y)).

Next, a second primitive flare vector in the z-direction is given as Flare2(x,y), which is expressed as:

Flare2(x,y)=|Mask(x,y)|×Gauss(x,y,DL) (2)

The first primitive flare vector and the second primitive flare vector is then combined, assuming tentative horizontal ratio as ηx=ηy, and tentative vertical ratio as ηz, to thereby define the flare electric field vector as (ηx*σx*Flare1(x,y), ηy*σy*Flare1(x,y), ηz*Flare2(x,y)) having a form of three-dimensional vector.

Therefore, the light intensity is given by adding the electric field vector and the flare electric field vector on the component basis, and by calculating a sum of squares of the individual components, as expressed by the equation below:

I(x,y)=(Ex(x,y)+ηx*σx*Flare1(x,y))²+(Ey+ηy*σy*Flare1(x,y))²+(Ez+ηz*Flare2(x,y))² (3)

On the other hand, also the threshold value is given as an unknown constant α independent of x,y. Provision such that ηx=ηy and ηz are defined as unknown for the convenience's sake, may be solved by a strategy such that also ηx=ηy and ηz are handled as adjustment constants similarly to the optical parameters, and the threshold value is optimized by regressive calculation or statistical processing, so that the CD identical to the measured CD can be obtained by calculation.

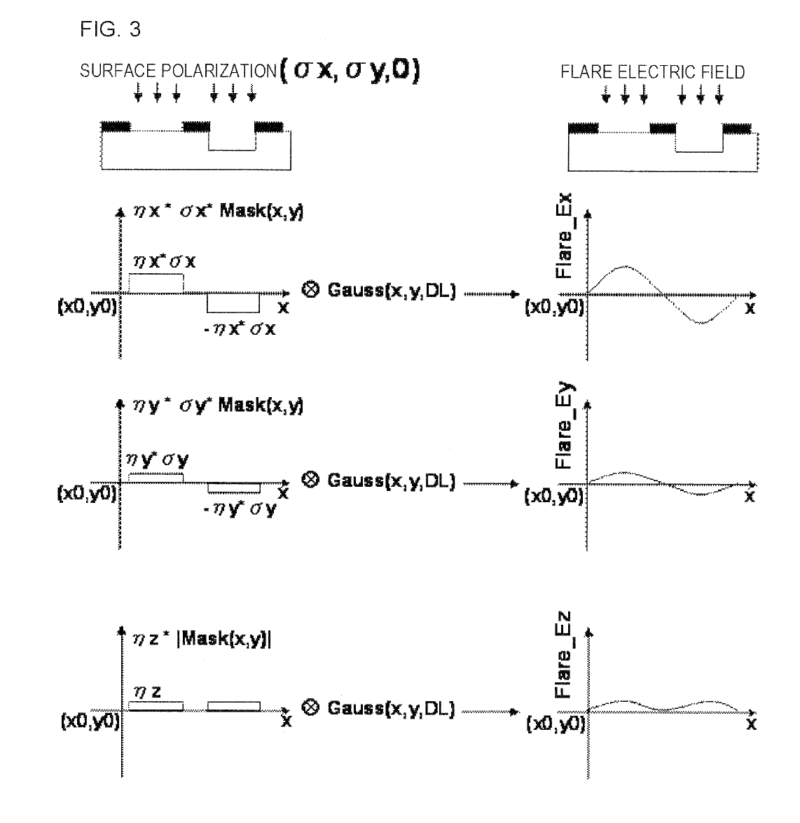

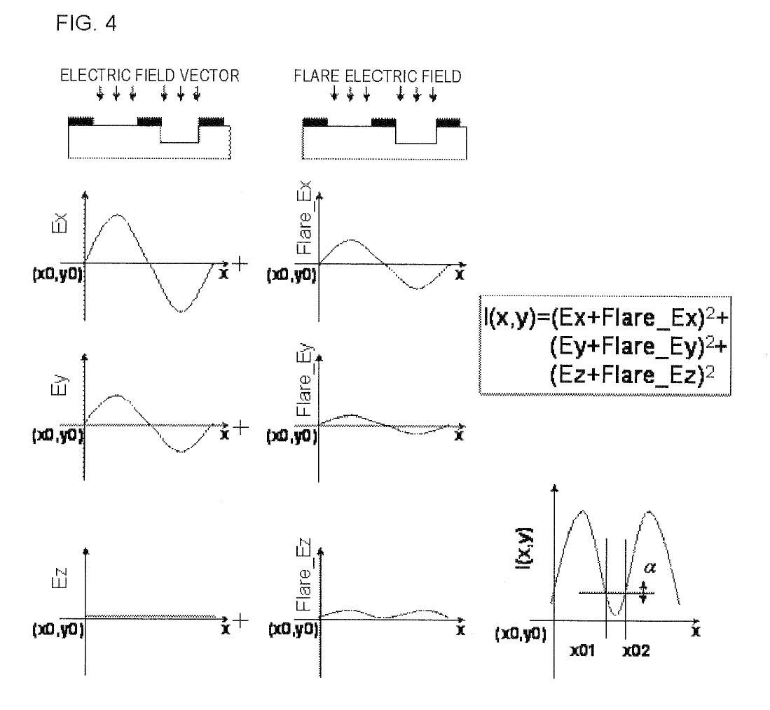

This will more specifically be explained referring to FIG. 3 and FIG. 4.

(A) Design value (mask CD) and measured value (measured CD) are given.

(B) As shown in FIG. 4, the electric field vector is obtained by calculation in the lithographic simulation.

(C) As shown in FIG. 3, the flare electric field vector can be calculated, if a mask pattern or mask function (Mask(x,y)), surface polarization (σx,σy,0), diffusion length DL, and horizontal ratio (ηx=ηy)/vertical ratio (ηz) are given.

(D) As shown in FIG. 4, light intensity can be obtained based on the electric field vector and the flare electric field vector.

(E) The threshold value defining the edge is given as a fixed unknown constant α.

(F) If the light intensity is given, and the threshold value is varied at around both edges composing the calculated value (calculated CD), a value where the calculated value (calculated CD) and the measured value (measured CD) come into agreement is uniquely determined.

(G) A lithographic model is determined by regressive calculation, under a condition of minimizing difference between the calculated value (calculated CD) and the measured value (measured CD). In this process, also diffusion length DL of photochemical reaction, horizontal ratio/vertical ratio, and the threshold value α, which have been given as unknown constants, are determined.

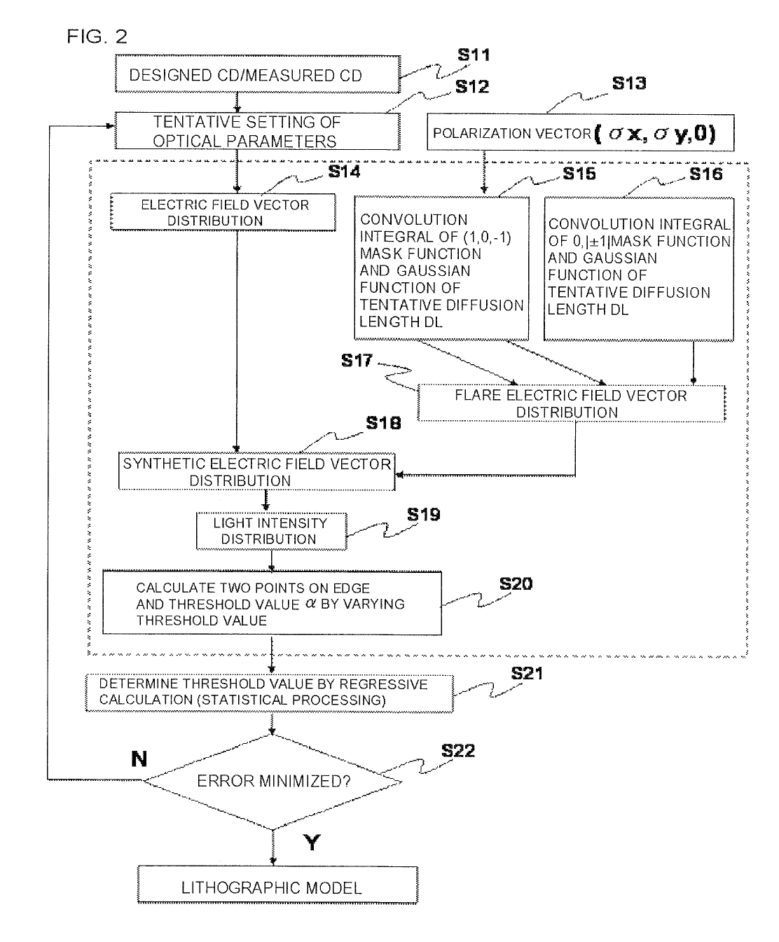

Next, operations of the simulation system 1 will be detailed, referring to FIG. 2 which is a flow chart of the operation, and FIG. 3 and FIG. 4 showing essential calculation processes (steps surrounded by a broken line in FIG. 2). In the lithographic simulation, steps (a) to (l) below will be executed.

(a) The design value (design CD) and the measured value (measured CD) are prepared (S11).

(b) The optical parameters are tentatively determined

(c) The surface polarization is prepared (S13).

(d) The electric field vector at position (x,y) is calculated (S14).

(e) The first primitive flare is determined, and the first primitive flare vector is calculated based on the surface polarization and the tentative horizontal ratio (S15).

(f) The second primitive flare vector is calculated based on the tentative vertical ratio (S16).

(g) The first flare electric field vector is configured by the first primitive flare vector and the second primitive flare vector (S17).

(h) The electric field vector and the flare electric field vector are added (S18).

(i) A sum of squares of the vector components is calculated, and the light intensity distribution is calculated (S19).

(j) Two edges x01 (more accurately (x01,y00)) and x02 (more accurately (x02,y00)), where the calculated CD can be obtained as being agreed with the measured CD, and the threshold value α appears as the same value at two edges are determined by varying the threshold value under a light intensity signal I(x,y), (the threshold value, although defined as being identical herein, may be determined also for the case where the threshold value cannot be identical due to optical conditions or the like, under the conditions to be satisfied by the threshold value) (S20).

(k) The obtained threshold value is processed by regressive calculation (statistical processing) (S21).

(l) Whether difference between the calculated value (calculated CD) and the measured value (measured CD), or error, is minimized or not (S22) is judged. If a condition of minimizing the error is satisfied, the optical parameters, the diffusion length DL, the horizontal ratio/vertical ratio, and the threshold value, all of which being remained as the unknown constants, may be determined, to thereby complete the lithographic model. On the other hand, if the condition minimizing the error is not satisfied, the process returns back to step (b), and the processing is repeated until the condition is satisfied, by varying the optical parameters, the diffusion length DL, and the horizontal ratio/vertical ratio.

The condition, allowing thereunder minimization of the error between the calculated value (calculated CD) and the measured value (measured CD) in the above-described processing, may be exemplified as follows. For example, sum of squares of the difference between the calculated values (calculated CD) and the measured values (measured CD) may be divided by the number of run of measurement, and root mean square (rms) of the quotient should be smaller than the standard deviation of variation in the actually measured values, or the absolute value of differences between the calculated values (calculated CD) and the measured values (measured CD) should always be smaller than the maximum measurement error of the measurement at every point of measurement. The above-described variation in the measured values and maximum measurement error mean necessary accuracy, and in other words, the lithographic model is completed when the accuracy is reached. For this reason, the combination of the optical parameters, the diffusion length DL and the horizontal ratio/vertical ratio is not always given as a single set so far as the necessary level of accuracy is satisfied, although only a single lithographic model seems to be given in FIG. 2. If two or more sets of the lithographic model are completed, the one having an error smallest of all may be selected, or an appropriate one may be selected taking, for example, calculation speed when adopted to other applications such as verification of lithography or model-base OPC, into consideration.

Effects of the simulation method of the this embodiment will be explained below.

According to the simulation method of the first embodiment, a highly accurate lithographic model for OPC may be obtained, and a desired transfer pattern may be provided under high accuracy.

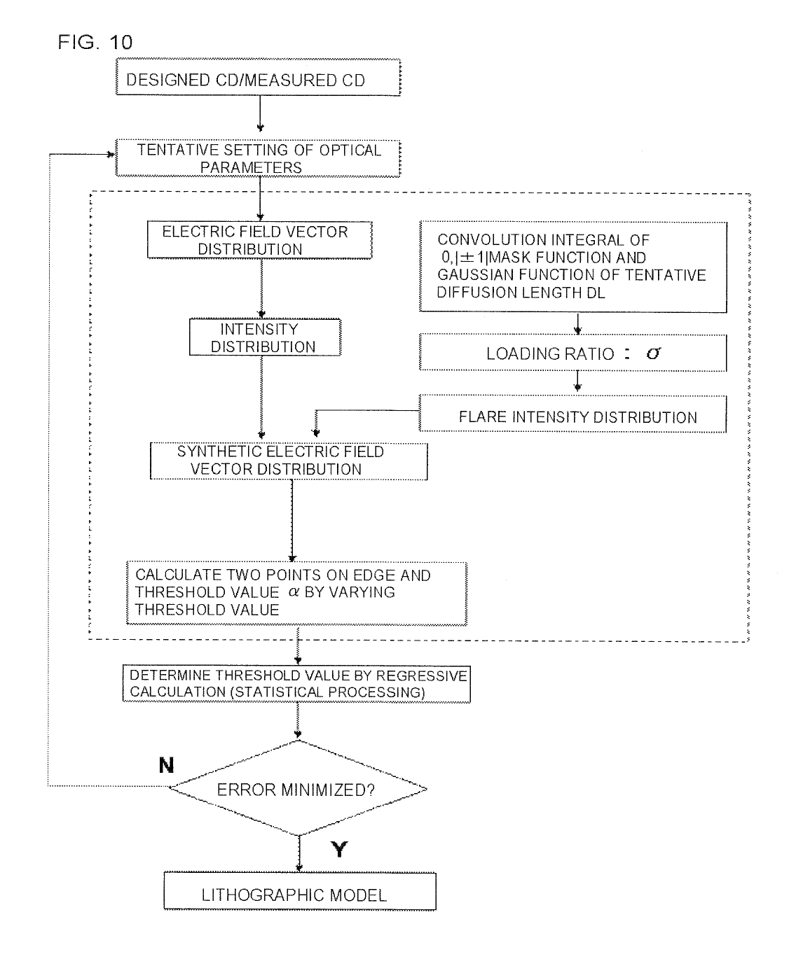

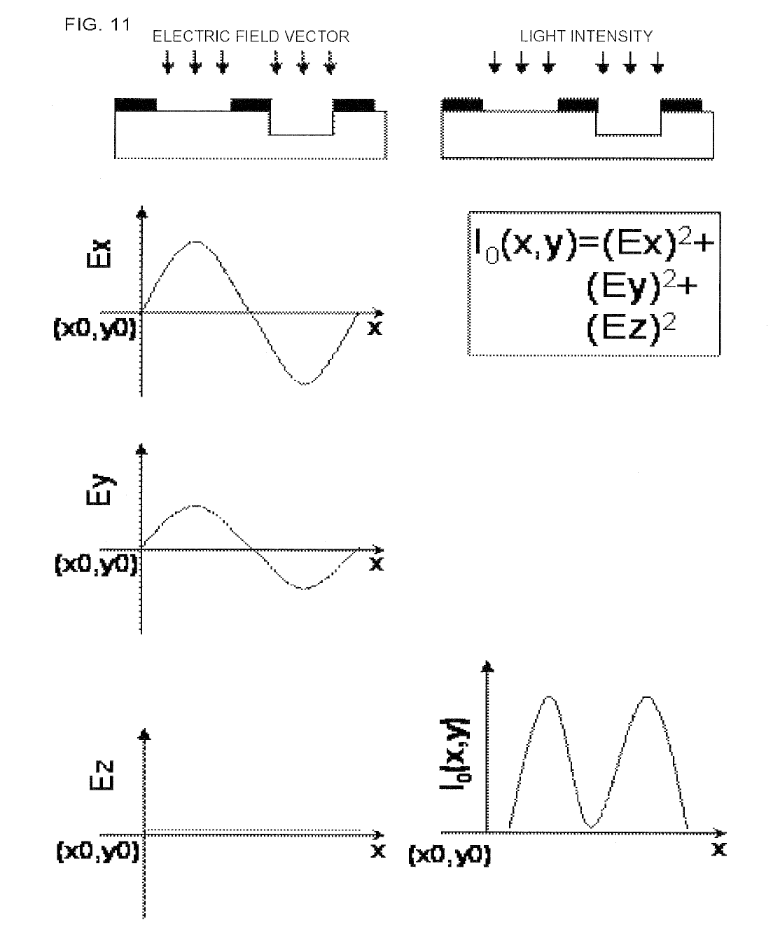

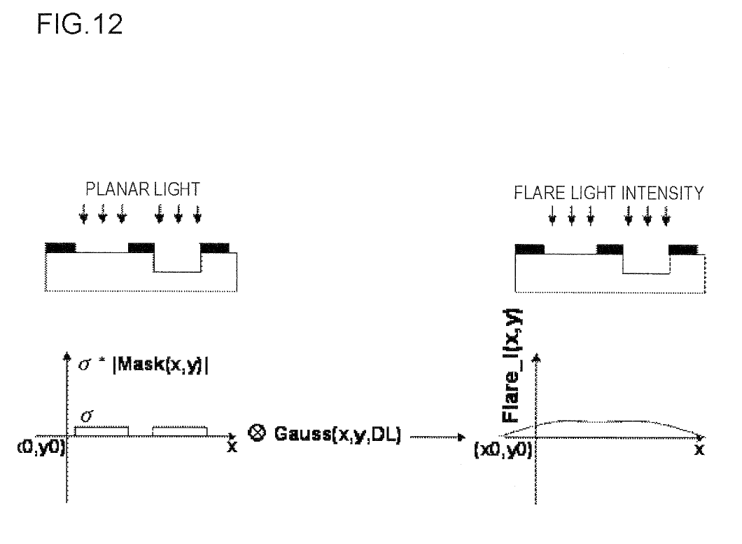

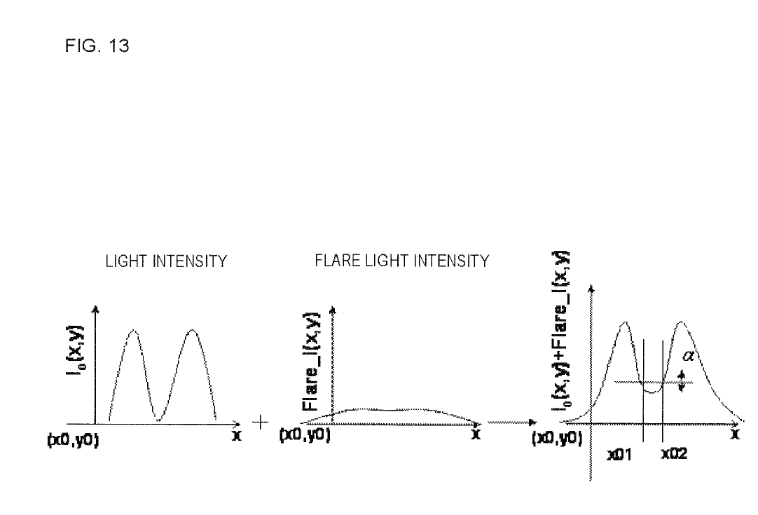

According to James Word, et al., as shown in the flow chart of FIG. 10, and further in FIG. 11 to FIG. 13 showing essential calculation processes in their simulation method (steps surrounded by a broken line in FIG. 10), light intensity distribution is calculated, a convolution integral of the opening of the mask pattern and Gaussian function of sigma (diffusion length, expressed as DL in this embodiment) is calculated, and the result is added as the loading effect to the above-described light intensity distribution.

This simulation method is only unsuccessfully applicable to a phase shift mask, for example, Levenson mask, showing failure in incorporating the loading effect within a narrow range as small as only 1 μm or less away from the point of origin of the influence. This is because the general stray light only behaves as the background light so as to enhance the light intensity, but the π-phase stray light contaminating the region illuminated by the 0-phase light may decrease the light intensity. In other words, the method cannot take pattern density dependence of coherent pattern into consideration.

In contrast, the lithographic simulation of the present invention incorporates the loading effect by determining the electric field vector having components in the x, y, z directions of the coordinate on the wafer plane, and by adding the flare electric field vector to the electric field vector. Moreover, the light intensity distribution is obtained by adding, as the electric field components, the loading effect in the electric field based on the surface polarization and the mask pattern. Therefore, the density dependence of coherent pattern may be taken into consideration even when a phase shift mask strongly susceptible to polarization is used, and thereby a highly accurate lithographic model for OPC may be obtained, and a desired transfer pattern may be obtained under high accuracy.

The first embodiment of a method of correcting a mask pattern according to the present invention is to correct the mask pattern, using the lithographic model obtained by the simulation method of this embodiment.

The first embodiment of a photomask according to the present invention has a corrected mask pattern obtained by the method of correcting a mask pattern of this embodiment. More specifically, fitting parameters are determined by the simulation method of this embodiment, optimum corrected pattern and optimum amount of correction are determined, based on which a corrected mask pattern is generated, and a photomask is then manufactured.

The first embodiment of a method of manufacturing a semiconductor device according to the present invention includes forming a resist film on a substrate; forming a pattern in said resist film by light exposure through the photomask according to this embodiment, and development; and processing the substrate using the resist film having the pattern transferred thereto.

The above-described process steps may be carried out according to general method of manufacturing semiconductor devices. “Processing the substrate” in this context may be understood as containing a series of process steps from the step of removing a film to be etched formed on the substrate, up to completion of the semiconductor device, effected through a resist film having the transferred pattern.

### SECOND EMBODIMENT

A second embodiment of the simulation system and the simulation method according to the present invention will be explained. A block configuration of the simulation system according to the second embodiment is same as the first embodiment (see FIG. 1).

In the second embodiment, the ternary phase shift mask having a value set of (1,0,−1) is replaced by a binary mask having a value set of (0,1), so that functions of the flare electric field vector calculation unit 34 differ from those in the first embodiment.

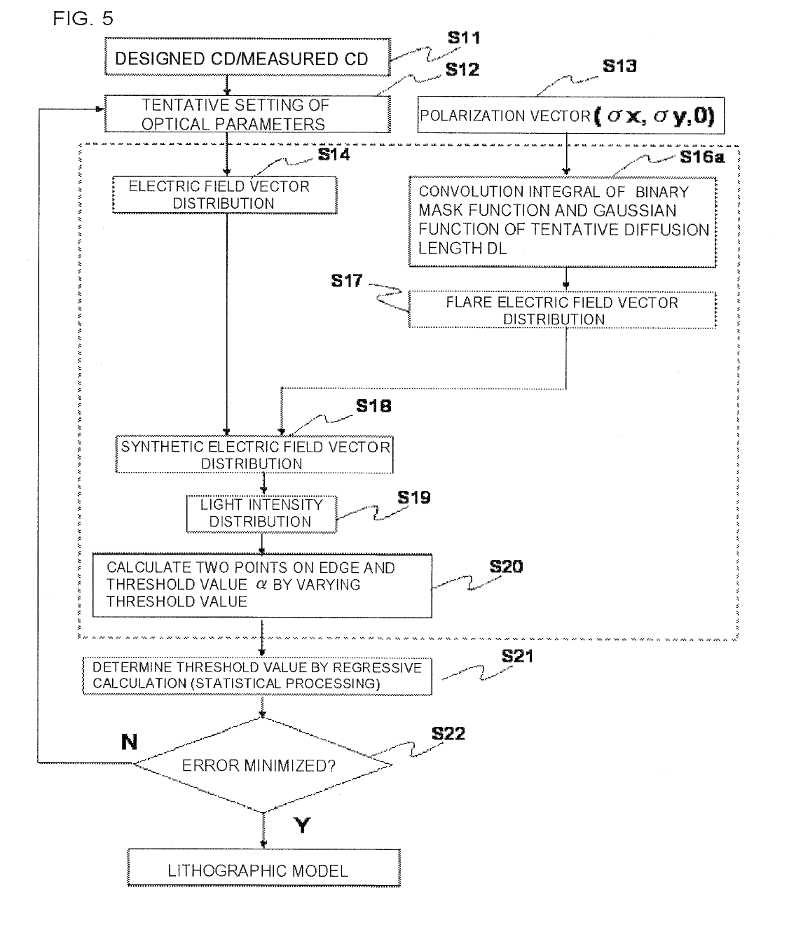

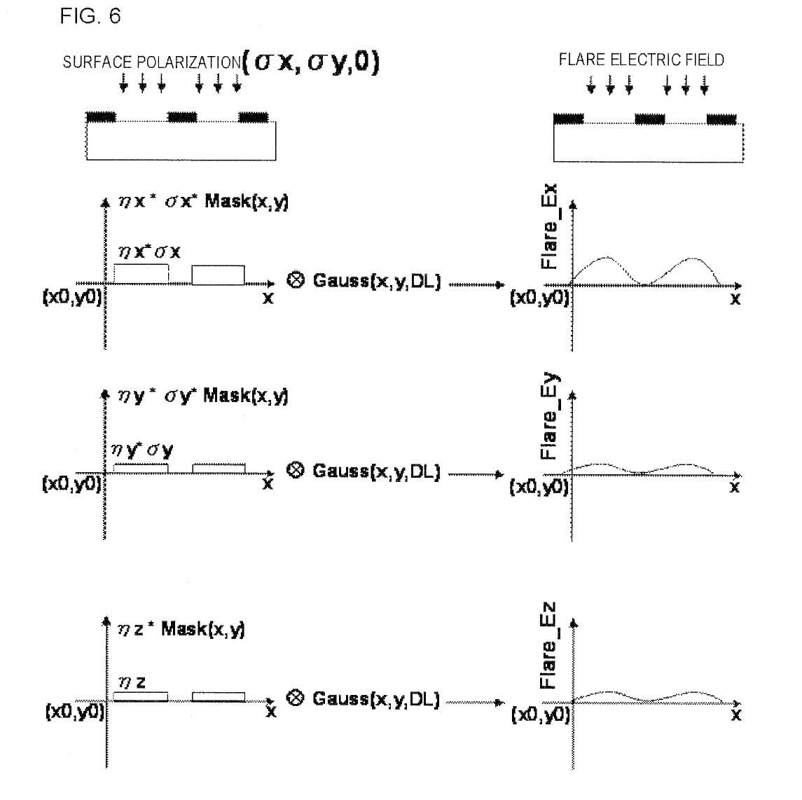

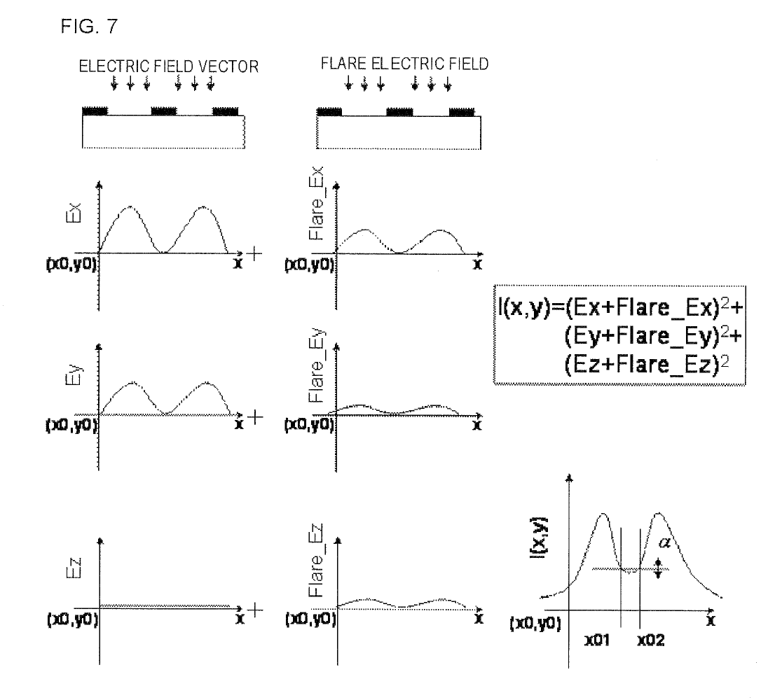

The operations will be detailed, referring to FIG. 5 which is a flow chart of the operation, and FIG. 6 and FIG. 7 showing essential calculation processes (steps surrounded by a broken line in FIG. 5). Steps S11 to S14, and steps S17 to S22 are same as those in the first embodiment (see FIG. 2), and will not be explained here.

Since the binary mask is used, the mask function Mask(x,y) obtained after step S16a has a value of (0,+1) corresponding to position (x,y). Value 0 corresponds to the shadowing region, and value +1 to the 0-phase opening region. The first primitive flare Flare1(x,y) of the binary mask is given identical to the equation (1).

Given the surface polarization of the exposure tool as (σx,σy,0), the first primitive flare vector defined only in a plane is given as (σx*Flare1(x,y), σy*Flare1(x,y)).

Next, the second primitive flare vector in the z-direction of the binary mask is given identical to the equation (2). This is identical to the equation (1) since the binary mask is used herein.

The first primitive flare vector and the second primitive flare vector is then combined, assuming tentative horizontal ratio as ηx=ηy, and tentative vertical ratio as ηz, to thereby define the flare electric field vector as (ηx*σx*Flare1(x,y), ηy*σy*Flare1(x,y), ηz*Flare1(x,y)) having a form of three-dimensional vector.

This embodiment deals with the case of using the binary mask. As a consequence, accuracy in the lithographic simulation using the binary mask, having a large NA, and causative of strong polarization effect due to incident light from oblique directions, may be improved. Other effects of this embodiment are similar to those in the first embodiment.

The second embodiment of the method of correcting a mask pattern according to the present invention is to correct the mask pattern, using the lithographic model obtained by the simulation method of this embodiment.

It is to be noted that, any influences of post-baking after the light exposure, which are processes of annealing the resist, possibly taken into consideration may be obtained by calculating a convolution integral of the light intensity and Gaussian function expressing diffusion length depending on thermal diffusion, and will not be explained here.

The second embodiment of the photomask according to the present invention has a corrected mask pattern obtained by the method of correcting a mask pattern according to this embodiment. More specifically, fitting parameters are determined by the simulation method of this embodiment, optimum corrected pattern and optimum amount of correction are determined, based on which a corrected mask pattern is generated, and a photomask is then manufactured.

The second embodiment of a method of manufacturing a semiconductor device according to the present invention includes forming a resist film on a substrate; forming a pattern in said resist film by light exposure through the photomask according to this embodiment, and development; and processing the substrate using the resist film having the pattern transferred thereto.

The above-described process steps may be carried out according to general method of manufacturing semiconductor devices. “Processing the substrate” in this context may be understood as containing a series of process steps from the step of removing a film to be etched formed on the substrate, up to completion of the semiconductor device, effected through a resist film having the transferred pattern.

The simulation method and the simulation system, and the method of correcting a mask pattern, the photomask, the method of manufacturing a semiconductor device of the present invention are not limited to the above-described embodiments, and allowing various modifications instead.

In the above-described embodiment, the tentative diffusion length may range from 0.0 to 0.1 [μm] or around, ranges of the parameters of surface polarization may be given as −1≦σx≦1, −1≦σy≦1 and σx²+σy²=1, and ranges of the tentative horizontal ratio (ηx, ηy)/tentative vertical ratio (ηz) may be given as −0.2≦ηx≦0.2 and −0.2≦ηy≦0.2 or around, assuming that intensity of light is normalized to [0,1]. However, it is not essential that the tentative diffusion length and the tentative horizontal ratio/tentative vertical ratio fall in the above-described ranges, and they may fall out of the above-described ranges so far as the regressive calculation can converge. The present invention is preferably applicable also to photolithography for manufacturing of semiconductor devices, liquid crystal display devices and so forth.

It is apparent that the present invention is not limited to the above embodiment, that may be modified and changed without departing from the scope and spirit of the invention.

What is claimed is:

1. A simulation method acquiring, by simulation, information on a transfer pattern realizable on a wafer as a result of photolithographic transfer of a mask pattern of a predetermined mask, comprising:
accepting an entry of measured dimension of said transfer pattern;
calculating an electric field vector for every predetermined position in a plane coordinate defined on the surface of said wafer;
calculating a flare electric field vector ascribable to said mask pattern for said every predetermined position;
adding said flare electric field vector to said electric field vector, and obtaining sum of squares of their triaxial vector components, to thereby calculate a light intensity distribution;
assuming a threshold value of light intensity observed for the edges at paired two points specifying calculated dimension of said transfer pattern in the simulation as an unknown constant, and determining, by regressive calculation, said threshold value so as to minimize difference between said calculated dimension and said measured dimension under said light intensity.

2. The simulation method as claimed in claim 1,
wherein said predetermined mask is a phase shift mask, and
in said calculating a flare electric field vector ascribable to said mask pattern, a convolution integral of a mask function having a value of +1 for the 0-phase opening region, a value of −1 for the π-phase opening region, and a value of 0 for the shadowing region of the mask pattern, and Gaussian function having a tentative length of diffusion, is calculated as a first primitive flare, and said first primitive flare is then multiplied respectively by ratio of polarization in each of two orthogonal directions on a plane in parallel with the wafer, to thereby define a first primitive flare vector having the calculated products as the in-plane bidirectional components;
a convolution integral of a mask function having a value of +1 both for the 0-phase opening region and the π-phase opening region of the mask pattern, and Gaussian function having a tentative length of diffusion, is calculated as a second primitive flare vector normal to the wafer; and
said flare electric field vector is defined as a three-dimensional vector based on a combination of said first primitive flare vector multiplied by a tentative horizontal ratio and said second primitive flare vector multiplied by a tentative vertical ratio.

3. The simulation method as claimed in claim 1,
wherein said predetermined mask is a binary mask, and
in said calculating a flare electric field vector ascribable to said mask pattern, a convolution integral of a mask function having a value of 1 for the opening region, and a value of 0 for the shadowing region of the mask pattern, and Gaussian function having a tentative length of diffusion, is calculated as a first primitive flare, and said first primitive flare is then multiplied respectively by ratio of polarization in each of two orthogonal directions on a plane in parallel with the wafer, to thereby define a first primitive flare vector having the calculated products as the in-plane bidirectional components;
said first primitive flare per se is defined as a second primitive flare vector normal to the wafer;
said flare electric field vector is defined as a three-dimensional vector based on a combination of said first primitive flare vector multiplied by a tentative horizontal ratio and said second primitive flare vector multiplied by a tentative vertical ratio.

4. A method of correcting a mask pattern correcting said mask pattern using a lithographic model obtainable by the simulation method described in claim 1.

5. A simulation system acquiring, by simulation, information on a transfer pattern realizable on a wafer as a result of photolithographic transfer of a mask pattern of a predetermined mask, comprising:
a unit of accepting an entry of measured dimension of said transfer pattern;
a unit of calculating an electric field vector for every predetermined position in a plane coordinate defined on the surface of said wafer;
a unit of calculating a flare electric field vector ascribable to said mask pattern for said every predetermined position;
a unit of adding said flare electric field vector to said electric field vector, and obtaining sum of squares of their triaxial vector components, to thereby calculate a light intensity distribution; and
a unit of assuming a threshold value of light intensity observed for the edges at paired two points specifying calculated dimension of said transfer pattern in the simulation as an unknown constant, and determining, by regressive calculation, said threshold value so as to minimize difference between said calculated dimension and said measured dimension under said light intensity.

6. A photomask having a corrected mask pattern obtainable by the method of correcting a mask pattern described in claim 4.

7. A method of manufacturing a semiconductor device comprising:
forming a resist film on a substrate;
forming a pattern in said resist film by light exposure through said photomask described in claim 6, and development; and
processing said substrate using said resist film having said pattern transferred thereto.
